(19) United States
(12) Patent Application Publication
(10) Pub. No.: US 2010/0200981 A1
(43) Pub. Date: Aug. 12, 2010

(54) SEMICONDUCTOR PACKAGE AND METHOD OF MANUFACTURING THE SAME

(75) Inventors: Wen Pin HUANG, Tainan City (TW); Cheng Tsung Hsu, Pingtung County (TW); Cheng Lan Tseng, Kaohsiung City (TW); Chih Cheng Hung, Kaohsiung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., KAOHSIUNG (TW)

(21) Appl. No.: 12/642,081

(22) Filed: Dec. 18, 2009

Related U.S. Application Data
(60) Provisional application No. 61/150,801, filed on Feb. 9, 2009.

(30) Foreign Application Priority Data
Jun. 18, 2009 (TW) 098120387

(51) Int. Cl. H01L 23/49; H01L 21/56

(52) U.S. Cl. 257/692; 438/124; 257/690; 257/E23.024; 257/E23.116; 257/E21.502

(57) ABSTRACT

In a method of manufacturing a semiconductor package, a chip is disposed on a carrier. An inert gas is run around one end of a line portion of a copper bonding wire while the end is being formed into a spherical portion. The spherical portion is bonded to a pad of the chip. The chip and the copper bonding wire are sealed and the carrier is covered by a molding compound.

### CROSS REFERENCE TO RELATED APPLICATION

This application claims the priority benefit of U.S. Provisional Application Ser. No. 61/150,801, filed on Feb. 9, 2009, and Taiwan Patent Application Serial Number 098120387, filed on Jun. 18, 2009. The full disclosures of the above-identified applications are incorporated herein by reference.

### TECHNICAL FIELD

The disclosure is related to a method of manufacturing a semiconductor package, and more particularly to a method of manufacturing a semiconductor package including a wire bonding process.

### BACKGROUND

Referring to FIG. 1, according to a process for manufacturing a semiconductor package, a wire bonding process is widely applied to form an electrical connection between a pad 11 of a chip 10 and a pad 13 of a substrate 12 by using a bonding wire 14. Such a wire bonding process is mainly based on gold (Au) wires, but copper (Cu) wires have an advantage of low cost. Compared with gold, copper has better electric conductivity and thermal conductivity, whereby a copper bonding wire has a thinner wire diameter and better heat dissipation than an electrically comparable gold wire. However, copper has disadvantages of insufficient ductility and easy oxidation such that the utilization of copper bonding wires is limited.

Recently, copper bonding wires are mostly applied to chip pads of a big size or on low dielectric material (low-k) wafers, because the success of a wire bonding process using copper bonding wires depends on the structural strength of the chip pads. In order to avoid the failure of the wire bonding process using copper bonding wires, there is a limit on how small the chip pads can be.

FIGS. 2 to 4 are cross-sectional views depicting several steps in a known method of bonding a copper bonding wire. Referring to FIG. 2, a copper bonding wire 20 is provided by a wire bonding machine, wherein the copper bonding wire 20 includes a copper line 22. One end of the copper line 22 is formed into a copper ball 24, which is physically connected to the copper line 22, by an electrical sintering process. Referring to FIG. 3, the copper ball 24 is pressed and then deformed. Referring to FIG. 4, the deformed copper ball 24 is bonded to an aluminum pad 32 by a vibration process.

However, the sintering temperature is high during the electrical sintering process of the copper ball 24, and thus copper is easily oxidized, whereby the shape of the copper ball 24 is unsuccessful (i.e., the shape of the copper ball 24 is not spherical). Furthermore, the hardness of copper is higher than that of aluminum, and thus the force applied from the copper bonding wire 20 during the pressing and vibrational processes possibly extrudes an aluminum material 34 of the aluminum pad 32 to a position around the copper ball 24.

### SUMMARY

In some embodiments, a semiconductor package comprises a carrier, a chip, a copper bonding wire, and a molding compound. The chip is disposed on the carrier and has a pad on a surface thereof. The copper bonding wire electrically connects the chip to the carrier. The copper bonding wire comprises a line portion and a bond where the copper bonding wire is bonded to the pad. The molding compound seals the chip and the copper bonding wire, and covers the carrier. The pad has an exposed region to which the copper bonding wire is bonded, and the distance between adjacent edges of the bond and the exposed region of the pad is not smaller than 4 μm.

In further embodiments, a semiconductor package comprises a carrier, a chip, a plurality of copper bonding wires, and a molding compound. The chip has an active surface and a back surface opposite to the active surface, and includes a plurality of first pads on the active surface. The carrier has a supporting surface and includes a plurality of second pads. The chip is disposed on the supporting surface of the carrier. The copper bonding wires electrically connect the first pads to the second pads, respectively. Each of the copper bonding wires comprises a line portion and a bond where the copper bonding wire is bonded to the respective first or second pad. The pad has an exposed region to which the copper bonding wire is bonded. The distance between adjacent edges of the bond and the exposed region of the pad is not smaller than 4 μm. The exposed region of the pad has a wire-contacting region and a non-wire-contacting region, and the non-wire-contacting region includes a residual material of at least one of the copper bonding wire and the pad extruded around the bond when the copper bonding wire is bonded to the pad. The molding compound seals the chip and the copper bonding wires, and covers the carrier.

In yet further embodiments, a method of manufacturing a semiconductor package comprises disposing a chip on a carrier, wherein the chip has an active surface with a pad thereon and a back surface opposite to the active surface. A copper bonding wire comprising a line portion is provided. An inert gas is run around an end of the line portion while the end of the line portion is being formed into a spherical portion. The spherical portion is bonded to the pad. The chip and the copper bonding wire are sealed and the carrier is covered by a molding compound to obtain the semiconductor package.

### BRIEF DESCRIPTION OF THE DRAWINGS

Exemplary embodiments will be discussed herein with reference to the accompanying drawings, wherein elements having the same reference numeral designations represent like elements throughout and wherein:

FIG. 1 is a cross-sectional view showing a known method of bonding a bonding wire;

FIGS. 2 to 4 are cross-sectional views showing several steps of a known method of bonding a copper bonding wire;

FIG. 5 is a cross-sectional view of a carrier and a chip for use in a method of manufacturing a semiconductor package;

FIG. 6 is a cross-sectional view of a copper bonding wire before sintering;

FIG. 7 is a cross-sectional view of a copper bonding wire after sintering in accordance with some embodiments;

FIG. 8 is a cross-sectional view showing a line portion and a spherical portion of the copper bonding wire after sintering;

FIG. 9 is a cross-sectional view of a copper/palladium bonding wire after sintering in accordance with further embodiments;

FIG. 10 is a cross-sectional view of a copper bonding wire after pressing in accordance with one or more embodiments;

FIG. 11 is a cross-sectional view of a copper bonding wire after bonding in accordance with one or more embodiments;

FIG. 12 is a cross-sectional view showing a line portion and an enlarged portion the copper bonding wire after bonding;

FIG. 13 is a cross-sectional view of the chip and the copper bonding wire being sealed within and of the carrier being covered by a molding compound in accordance with some embodiments;

FIG. 14 is a cross-sectional view of a semiconductor package according to further embodiments; and

FIG. 15 is a cross-sectional view of a semiconductor package according to yet further embodiments.

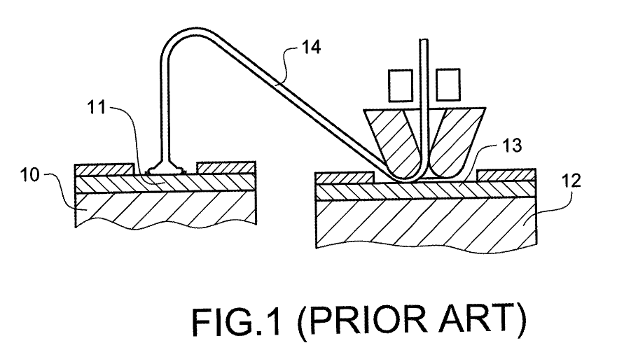

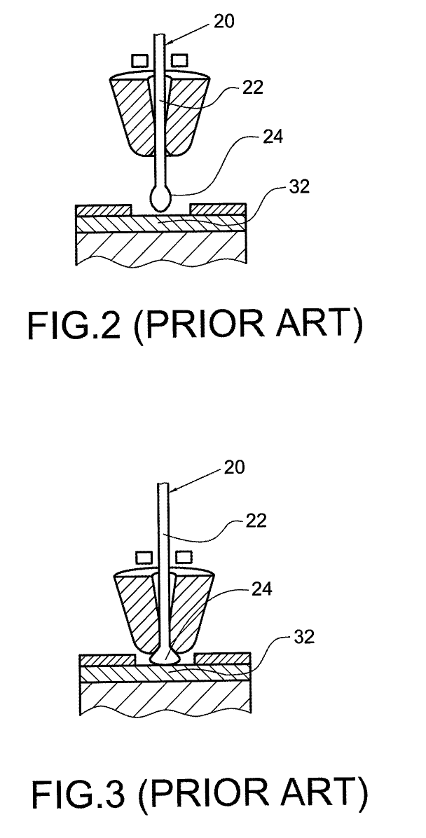

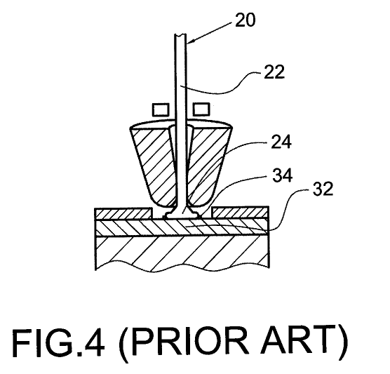

### DETAILED DESCRIPTION

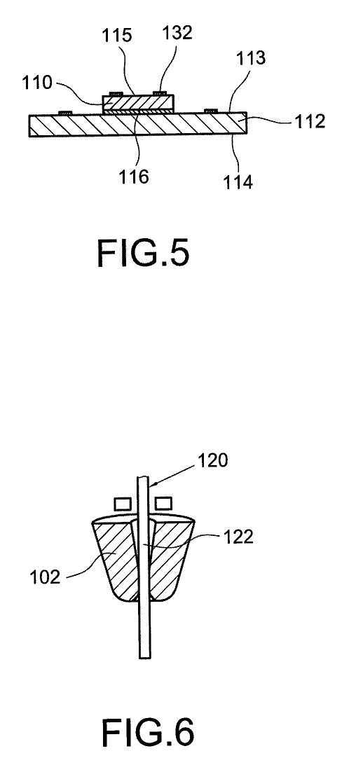

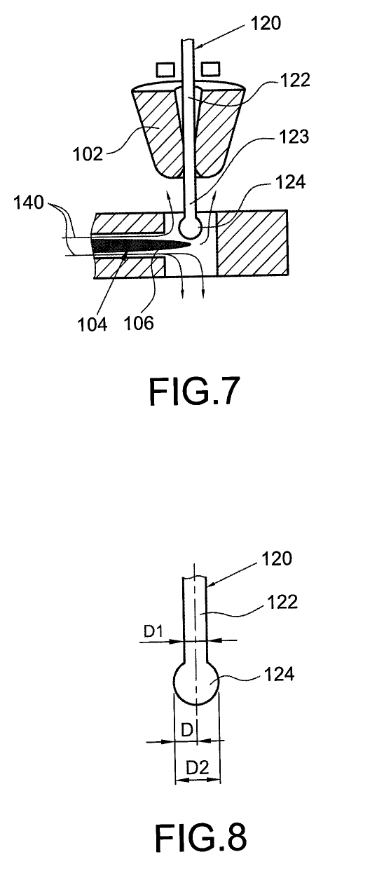

Referring to FIG. 5, a carrier 112 is provided, wherein the carrier 112 has an upper surface 113 and a lower surface 114 opposite to the upper surface 113. A chip 110 is disposed on the carrier 112, wherein the chip 110 has an active surface 115 and a back surface 116 opposite to the active surface 115. At least one pad 132 (e.g., an aluminum pad) is disposed on the active surface 115 of the chip 110. Referring to FIG. 6, in this particularly illustrated embodiment, a copper bonding wire 120 is provided by a wire bonding machine 102, wherein the copper bonding wire 120 includes a line portion 122. Referring to FIG. 7, an inert gas 140 is run around the neighborhood of one end 123 of the line portion 122, and the end 123 of the line portion 122 is formed into a spherical portion 124 by an electrical sintering process, e.g., a sintering process using electrical discharges in a high-voltage electrical flame-off (EFO) device 104. More particularly, when an ignition electrode 106 of the EFO device 104 is moved toward the end 123 of the line portion 122 so that the gap between the ignition electrode 106 and the end 123 of the line portion 122 is decreased to less than a predetermined value, a high-voltage electrical discharge will appear between the ignition electrode 106 of the EFO device 104 and the end 123 of the line portion 122. The high-voltage electrical discharge quickly melts the end 123 of the line portion 122, and the shape of the end 123 of the line portion 122 is formed into a spherical shape due to surface tension and gravity. The weight percentage of copper element of the copper bonding wire 120 can be 99.9% (3N), 99.99% (4N) or 99.999% (5N). The inert gas 140 (e.g., the nitrogen gas) effectively separates copper in the end 123 from contacting oxygen during the electrical sintering process of the spherical portion 124 of the copper bonding wire 120, and thus copper is not easily oxidized, whereby the shape of the spherical portion 124 is successful (i.e., the shape of the spherical portion 124 is spherical), even if the sintering temperature is high. The inert gas 140 can greatly effectively separate copper from contacting oxygen during the electrical sintering process, when the inert gas 140 includes a mixture of the nitrogen gas and the hydrogen gas.

Referring to FIG. 8, the spherical portion 124 of the copper bonding wire 120 is physically connected to the line portion 122, and the cross-sectional area of the spherical portion 124 is larger than that of the line portion 122. The shape of the spherical portion 124 is considered “successful” if the distance D from the outer surface of the spherical portion 124 to the centerline of the copper bonding wire 120 is substantially the same on either side of the centerline. Alternatively or additionally, the shape of the spherical portion 124 is considered “successful” if the diameter D1 of the line portion 122 and the diameter D2 of the spherical portion 124 meet the following requirement: 2×D1≦D2≦2.5×D1. Table 1 below shows the sintering current and the sintering time of the EFO device 104, the diameter D1 of the line portion 122 and the diameter D2 of the spherical portion 124 in accordance with some embodiments.

TABLE 1

| | D1 = 20 μm | | | | D1 = 23 μm | | D1 = 25 μm | | |
|---|---|---|---|---|---|---|---|---|---|
| sintering | 50~70 | 70~90 | 90~110 | 100~120 | 85~95 | 100~110 | 50~70 | 90~110 | 110~125 |
| current (mA) | | | | | | | | | |
| sintering | 170~220 | 150~170 | 110~120 | 90~110 | 170~190 | 160~170 | 400~430 | 250~260 | 180~220 |
| time (ms) | | | | | | | | | |

| | | | |
|---|---|---|---|
| D2 | 40~50 μm | 45~58 μm | 50~63 μm |

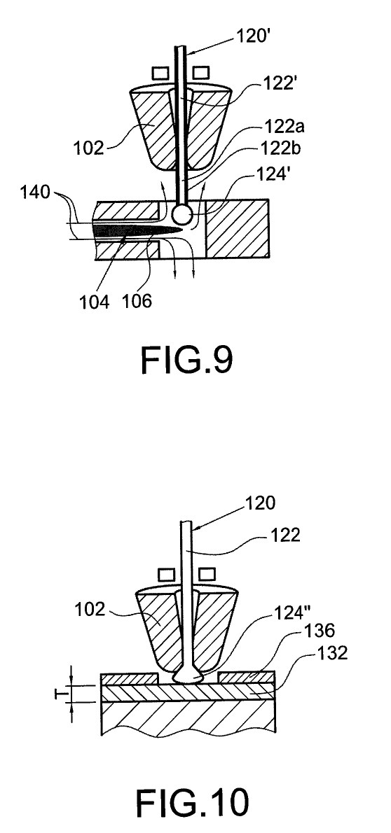

Referring to FIG. 9, in further embodiments, the line portion of the copper bonding wire is sealed (or covered) by an anti-oxidative metal. The anti-oxidative metal can be palladium (Pd), i.e., the copper bonding wire 120 can be replaced with a copper/palladium bonding wire 120′. The line portion 122′ includes a copper body 122a and a palladium layer 122b, and the palladium layer 122b seals or covers the copper body 122a. The spherical portion 124′ likewise includes a copper core and a palladium cover. The weight percentage of palladium element of the copper/palladium bonding wire 120′ can be between 0.8% and 2.7%.

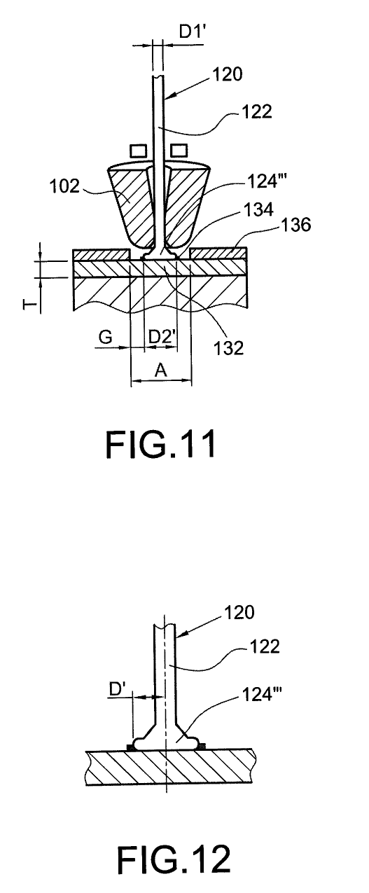

The spherical portion 124 (or 124′) of the copper bonding wire 120 (or 120′) is bonded to the pad 132 so as to finish the wire bonding process. More particularly, referring to FIG. 10, the spherical portion 124 of the copper bonding wire 120 is located above the pad 132, and then the spherical portion 124 is pressed and deformed into a non-spherical portion 124″. Referring to FIG. 11, the non-spherical portion 124″ is bonded to the pad 132 by a vibration process (e.g., a supersonic vibration process), thereby forming a wire bonding structure having a bond 124′″. After the non-spherical portion 124″ is bonded to the pad 132 and becomes the bond 124′“, the cross-section of the line portion has a diameter D1′ and the cross-section of the bond 124′” has a diameter D2′. Generally, the diameter D1' is the same as diameter D1. Further, the diameter D1′ of the line portion 122 and the diameter D2′ of the bond 124′″ satisfy the following requirement: 1.8×D1′≦D2′≦3×D1′. Table 2 below shows the diameter D1′ of the line portion 122 and the diameter D2′ of the bond 124′″.

TABLE 2

| | D1′ = 20 μm | D1′ = 23 μm | D1′ = 25 μm |
|---|---|---|---|
| D2′ | 36~60 μm | 41~69 μm | 44~75 μm |

Furthermore, the hardness of copper is higher than that of aluminum, and thus the force applied from the copper bonding wire 120 during the pressing and vibration processes possibly extrudes a residual material 134 (e.g., the aluminum material of the aluminum pad 132 and/or the copper material of the copper bonding wire 120) to a position around the bond 124′″, as shown in FIG. 11. The chip 110 includes a passivation layer 136, which is formed on the active surface 115 while exposing the pad 132, whereby the pad 132 has an exposed region A. If the thickness of the pad 132 is between 0.8 μm and 2.5 μm before bonding, the distance G between adjacent edges of the bond 124′″ and the exposed region A of the pad 132 is larger than or equal to 4 μm, so that the force applied from the copper bonding wire 120 during the pressing and vibrational processes cannot extrude the residual material 134 to another pad or another copper bonding wire, so as to avoid a short circuit. The distance G between the adjacent edges of the bond 124′″ and the exposed region A of the pad 132 is also larger than or equal to 4 μm, if there are at least one copper layer (or aluminum layer) and a low-k dielectric layer (not shown) located under the pad 132, and the total thickness of the pad, the copper layer (or aluminum layer) and the dielectric layer is between 1.2 μm and 1.5 μm before bonding. Furthermore, referring to FIG. 12, the distance D′ from the edge of the bond 124′″ to the centerline of the copper bonding wire 120 is substantially the same on either side of the centerline.

In further embodiments, the bond 124′″ (shown in FIG. 12) includes a mixture of copper and palladium, if the copper bonding wire 120 is replaced with a copper/palladium bonding wire 120′ (shown in FIG. 9).

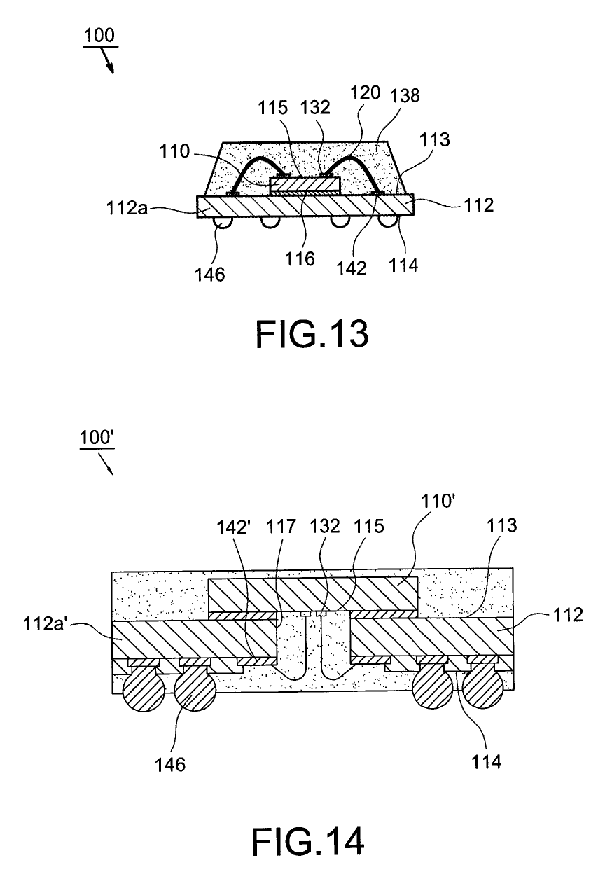

Referring to FIG. 13, in a particular embodiment, the carrier 112 is a substrate 112a. One end of the copper bonding wire 120 is electrically connected to the pad 132 (i.e., the first pad) of the chip 110, and the other end of the copper bonding wire 120 is electrically connected to the pad 142 (i.e., the second pad) of the substrate 112a. There may be more than one first and/or second pads. The pad 132 of the chip 110 is electrically connected to the circuit (not shown) of the chip 110. The substrate 112a includes external electrical contacts 146 located on the lower surface 114.

After the wire bonding process, the chip 110 and the copper bonding wire 120 are sealed and the carrier 112 is covered by a molding compound 138, whereby the molding compound 138, the chip 110 and the carrier 112 are formed into a ball grid array (BGA) package 100. In some embodiments, the composition of the molding compound 138 includes chlorine ions and sodium ions, whereby the copper bonding wire 120 is not easily oxidized. Alternatively or additionally, the composition of the molding compound 138 includes bromine ions. The pH value of the molding compound 138 is between 4 and 7 whereby the copper bonding wire 120 is not easily oxidized.

The semiconductor package 100 as shown in FIG. 13 includes the carrier 112, the chip 110, the pad 132 (e.g., an aluminum pad), the copper bonding wire 120 (or a copper/palladium wire 120′) and the molding compound 138. The carrier 112 has the upper surface 113 (i.e., the supporting surface) and the lower surface 114 opposite to the upper surface 113. The chip 110 has the active surface 115 and the back surface 116 opposite to the active surface 115, and the back surface 116 of the chip 110 is disposed on the upper surface 113 of the carrier 112, i.e., the back surface 116 of the chip 110 is disposed on the supporting surface of the carrier 112. The pad 132 is disposed on the active surface 115 of the chip 110. The copper bonding wire 120 electrically connects the chip 110 to the carrier 112, wherein the copper bonding wire 120 includes a line portion 122 and a bond 124′″ where the copper bonding wire 120 is bonded to the pad 132. The cross-section of the line portion 122 has a diameter D1′, the cross-section of the bond 124′″ has a diameter D2′ wherein 1.8×D1′≦D2′≦3×D1′. The distance between adjacent edges of the bond 124′″ and the exposed region of the pad 132 is not smaller than 4 μm. The molding compound 138 seals the chip 110 and the copper bonding wire 120, and covers the carrier 112.

The pad 132 has a wire-contacting region and a non-wire-contacting region, wherein the non-wire-contacting region includes the residual material 134 which is extruded when the copper bonding wire 120 is bonded to the pad 132. The residual material 134 includes at least one of aluminum, copper, and palladium as discussed above with respect to FIG. 11.

Referring to FIG. 14, in another embodiment, the disclosed wire bonding structure can also be applied to a cavity down type package, e.g., a W type ball grid array (WBGA) package 100′. The semiconductor package 100′ is similar to the semiconductor package 100. A noticeable difference between the semiconductor packages 100′ and 100 is that the active surface 115 of the chip 110′ is disposed on the upper surface 113 of the carrier 112 (e.g., the substrate 112a′). The substrate 112a′ includes a through hole 117, which extends from the upper surface 113 to the lower surface 114. The copper bonding wire 120 (or the copper/palladium bonding wire 120′) passes through the through hole 117, one end of the copper bonding wire 120 is electrically connected to the pad 132 (i.e., the first pad) of the chip 110′, and the other end of the copper bonding wire 120 is electrically connected to the pad 142 (i.e., the second pad) of the substrate 112a′. There may be more than one first and/or second pads. The pad 132 of the chip 110 is electrically connected to the circuit (not shown) of the chip 110. The substrate 112a′ includes external electrical contacts 146 located on the lower surface 114.

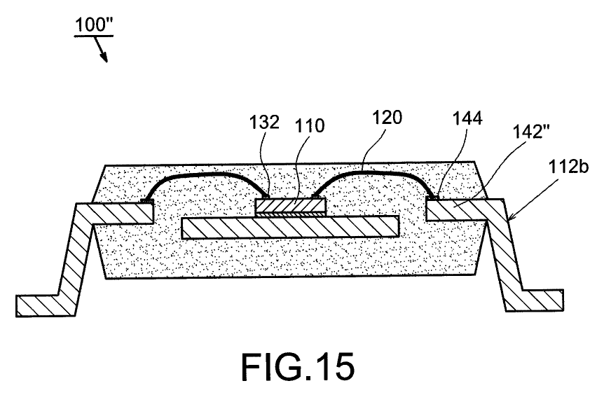

Referring to FIG. 15, in a further embodiment, the disclosed wire bonding structure can be applied to a package having a leadframe, i.e., a further semiconductor package 100″. The semiconductor package 100″ is similar to the semiconductor package 100. A noticeable difference between the semiconductor packages 100″ and 100 is that the carrier 112 is a leadframe 112b. The semiconductor package further includes a pad 142″of a lead and a metallic layer 144. The pad 142″ of the lead is disposed on the leadframe 112b. The metallic layer 144 covers the pad 142″of the lead. The metallic layer 144 can be one or more of silver (Ag), gold (Au) and palladium (Pd). The pad 142″of the lead is electrically connected to the copper bonding wire 120 (or the copper/palladium bonding wire 120′).

Although several embodiments have been disclosed in detail, it is to be understood that many other possible modifications and variations can be made by those skilled in the art without departing from the spirit and scope of the present disclosure.

What is claimed is:

1. A semiconductor package, comprising:
a carrier;
a chip disposed on the carrier and having a pad on a surface thereof;
a copper bonding wire electrically connecting the chip to the carrier, wherein the copper bonding wire comprises a line portion and a bond where the copper bonding wire is bonded to the pad; and
a molding compound sealing the chip and the copper bonding wire, and covering the carrier;
wherein the pad has an exposed region to which the copper bonding wire is bonded, and the distance between adjacent edges of the bond and the exposed region of the pad is not smaller than 4 μm.

2. The semiconductor package as claimed in claim 1, wherein a distance between an edge of the bond and the centerline of the copper bonding wire is substantially the same on either side of the centerline.

3. The semiconductor package as claimed in claim 1, wherein the exposed region of the pad has a wire-contacting region and a non-wire-contacting region, the non-wire-contacting region includes a residual material of at least one of the copper bonding wire and the pad extruded around the bond when the copper bonding wire is bonded to the pad.

4. The semiconductor package as claimed in claim 3, wherein the residual material is at least one selected from the group consisting of aluminum and copper.

5. The semiconductor package as claimed in claim 1, wherein the copper bonding wire further comprises an anti-oxidative metal sealing the line portion.

6. The semiconductor package as claimed in claim 1, wherein the thickness of the pad is between 0.8 μm and 2.5 μm.

7. The semiconductor package as claimed in claim 1, wherein the chip has at least one copper or aluminum layer and at least one dielectric layer which all are located under the pad, and the total thickness of the pad, the copper or aluminum layer and the dielectric layer is between 1.2 μm and 1.5 μm.

8. The semiconductor package as claimed in claim 1, wherein the molding compound comprises at least one selected from the group consisting of chlorine ions, bromine ions and sodium ions.

9. The semiconductor package as claimed in claim 1, wherein the pH value of the molding compound is between 4 and 7.

10. The semiconductor package as claimed in claim 1, wherein the carrier is one selected from the group consisting of a substrate and a lead frame.

11. A semiconductor package, comprising:
a chip having an active surface and a back surface opposite to the active surface, and including a plurality of first pads on the active surface;
a carrier having a supporting surface and including a plurality of second pads, wherein the chip is disposed on the supporting surface of the carrier;
a plurality of copper bonding wires electrically connecting the first pads to the second pads, respectively, wherein each of the copper bonding wires comprises a line portion and a bond where the copper bonding wire is bonded to the respective first or second pad, said pad has an exposed region to which the copper bonding wire is bonded, the distance between adjacent edges of the bond and the exposed region of the pad is not smaller than 4 μm, the exposed region of the pad has a wire-contacting region and a non-wire-contacting region, and the non-wire-contacting region includes a residual material of at least one of the copper bonding wire and the pad extruded around the bond when the copper bonding wire is bonded to the pad; and
a molding compound sealing the chip and the copper bonding wires, and covering the carrier.

12. The semiconductor package as claimed in claim 11, wherein the cross-section of the line portion has a diameter D1′, the cross-section of the bond has a diameter D2′, and 1.8×D1′≦D2′≦3×D1′.

13. The semiconductor package as claimed in claim 11, wherein the copper bonding wire further comprises an anti-oxidative metal sealing the line portion.

14. A method of manufacturing a semiconductor package, said method comprising:
disposing a chip on a carrier, wherein the chip has an active surface with a pad thereon and a back surface opposite to the active surface;
providing a copper bonding wire comprising a line portion;
running an inert gas around an end of the line portion while forming the end of the line portion into a spherical portion;
bonding the spherical portion to the pad; and
sealing the chip and the copper bonding wire, and covering the carrier by a molding compound to obtain the semiconductor package.

15. The method as claimed in claim 14, wherein the spherical portion is formed into a bond after said bonding, the cross-section of the line portion has a diameter D1' after said bonding, the cross-section of the bond has a diameter D2′, and 1.8×D1′≦D2′≦3×D′.

16. The method as claimed in claim 15, wherein, before said bonding, the line portion and the spherical portion have diameters D1 and D2, respectively, and 2×D1≦D2≦2.5×D1.

17. The method as claimed in claim 16, wherein a distance between an edge of the bond and a centerline of the copper bonding wire is substantially the same on either side of the centerline, and a distance between an edge of the spherical portion and the centerline of the copper bonding wire is also substantially the same on either side of the centerline.

18. The method as claimed in claim 14, wherein the inert gas comprises nitrogen gas or a mixture of nitrogen gas and hydrogen gas.

19. The method as claimed in claim 14, wherein the end of the line portion is formed to the spherical portion by an electrical sintering process.

20. The method as claimed in claim 14, wherein the molding compound comprises at least one selected from the group consisting of chlorine ions, bromine ions and sodium ions or has a pH value between 4 and 7 for limiting oxidization of the copper bonding wire.
